(19) United States
(12) Patent Application Publication
(10) Pub. No.: US 2016/0254053 A1
(43) Pub. Date: Sep. 1, 2016

(54) NONVOLATILE SEMICONDUCTOR MEMORY DEVICE AND METHOD OF MANUFACTURING THE SAME

(71) Applicant: KABUSHIKI KAISHA TOSHIBA, Minato-ku (JP)

(72) Inventors: Karin TAKAYAMA, Yokkaichi (JP); Takeshi Murata, Yokkaichi (JP)

(73) Assignee: KABUSHIKI KAISHA TOSHIBA, Minato-ku (JP)

(21) Appl. No.: 14/803,240

(22) Filed: Jul. 20, 2015

Related U.S. Application Data
(60) Provisional application No. 62/121,015, filed on Feb. 26, 2015.

(51) Int. Cl. G11C 16/04; H01L 27/115; G11C 16/32

(52) U.S. Cl. CPC G11C 16/0483; G11C 16/32; G11C 16/0408; H01L 27/11524

(57) ABSTRACT

According to an embodiment, a nonvolatile semiconductor memory device comprises: a memory string including a plurality of memory cells connected in series; a first select gate transistor connected to one end of this memory string; and a first voltage application circuit that controls this first select gate transistor. The first select gate transistor includes a plurality of first transistors connected in series. The first voltage application circuit performs application of a voltage so as to render the plurality of first transistors in a conductive state synchronously.

### CROSS REFERENCE TO RELATED APPLICATIONS

This application is based on and claims the benefit of priority from prior U.S. prior provisional Patent Application No. 62/121,015, filed on Feb. 26, 2015, the entire contents of which are incorporated herein by reference.

### FIELD

Embodiments described herein relate to a semiconductor memory device and a method of manufacturing the same.

### BACKGROUND

### Description of the Related Art

A memory cell configuring a semiconductor memory device such as a NAND type flash memory includes a semiconductor layer, a control gate, and a charge accumulation layer. The memory cell changes its threshold voltage according to a charge accumulated in the charge accumulation layer and stores a magnitude of this threshold voltage as data. Moreover, a plurality of such memory cells are connected in series to configure a memory string. Select gate transistors are respectively connected to both ends of the memory string. The memory string is selectively connected to a control circuit by this select gate transistor. In recent years, as the level of integration of such a semiconductor memory device rises, it has sometimes occurred that processing or control of the select gate transistor becomes difficult.

### BRIEF DESCRIPTION OF THE DRAWINGS

FIG. 1 is a block diagram showing a schematic configuration of a nonvolatile semiconductor memory device according to a first embodiment.

FIG. 2 is a circuit diagram showing a configuration of part of the same nonvolatile semiconductor memory device.

FIG. 3 is a schematic plan view showing a configuration of part of the same nonvolatile semiconductor memory device.

FIG. 4 is a schematic plan view showing a configuration of part of the same nonvolatile semiconductor memory device.

FIG. 5 is a schematic cross-sectional view showing a configuration of part of the same nonvolatile semiconductor memory device.

FIG. 6 is a schematic cross-sectional view showing a configuration of part of the same nonvolatile semiconductor memory device.

FIG. 7 is a schematic cross-sectional view showing a configuration of part of the same nonvolatile semiconductor memory device.

FIG. 8 is a cross-sectional view showing a manufacturing step of the same nonvolatile semiconductor memory device.

FIG. 9 is a cross-sectional view showing a manufacturing step of the same nonvolatile semiconductor memory device.

FIG. 10 is a cross-sectional view showing a manufacturing step of the same nonvolatile semiconductor memory device.

FIG. 11 is a cross-sectional view showing a manufacturing step of the same nonvolatile semiconductor memory device.

FIG. 12 is a cross-sectional view showing a manufacturing step of the same nonvolatile semiconductor memory device.

FIG. 13 is a cross-sectional view showing a manufacturing step of the same nonvolatile semiconductor memory device.

FIG. 14 is a cross-sectional view showing a manufacturing step of the same nonvolatile semiconductor memory device.

FIG. 15 is a cross-sectional view showing a manufacturing step of the same nonvolatile semiconductor memory device.

FIG. 16 is a cross-sectional view showing a manufacturing step of the same nonvolatile semiconductor memory device.

FIG. 17 is a cross-sectional view showing a manufacturing step of the same nonvolatile semiconductor memory device.

FIG. 18 is a cross-sectional view showing a manufacturing step of the same nonvolatile semiconductor memory device.

FIG. 19 is a schematic cross-sectional view showing a configuration of part of a nonvolatile semiconductor memory device according to a second embodiment.

### DETAILED DESCRIPTION

A semiconductor memory device according to an embodiment described below comprises: a memory string including a plurality of memory cells connected in series; a first select gate transistor connected to one end of this memory string; and a first voltage application circuit that controls this first select gate transistor. The first select gate transistor includes a plurality of first transistors connected in series. The first voltage application circuit performs application of a voltage so as to render the plurality of first transistors in a conductive state synchronously.

Embodiments of a semiconductor memory device and a method of manufacturing the same will be described below with reference to the drawings. Note that voltage values and so on shown in the specification are merely illustrative, and may be appropriately changed.

### First Embodiment

### Overall Configuration

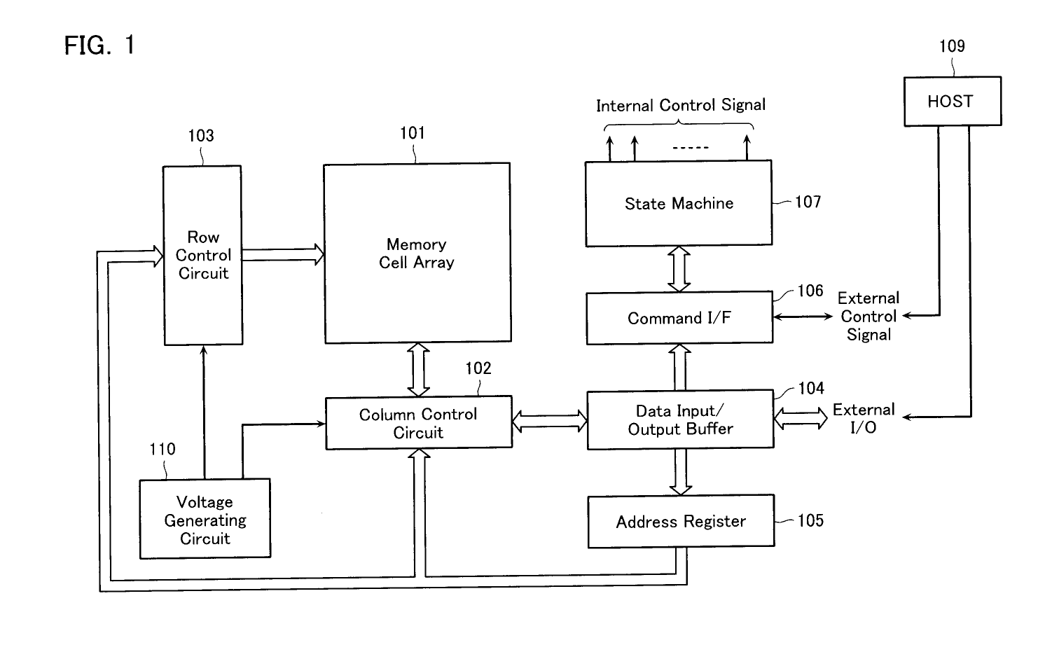

FIG. 1 is a block diagram of a nonvolatile semiconductor memory device according to a first embodiment. This nonvolatile semiconductor memory device includes a memory cell array 101 having a plurality of memory cells MC disposed substantially in a matrix therein, and comprising a bit line BL and a word line WL disposed orthogonally to each other and connected to these memory cells MC. Provided in a periphery of this memory cell array 101 are a column control circuit 102 and a row control circuit 103. The column control circuit 102 controls the bit line BL and performs data erase of the memory cell, data write to the memory cell, and data read from the memory cell. The row control circuit 103 selects the word line WL and applies a voltage for data erase of the memory cell, data write to the memory cell, and data read from the memory cell.

A data input/output buffer 104 is connected to an external host 109, via an I/O line, and receives write data, receives an erase command, outputs read data, and receives address data or command data. The data input/output buffer 104 sends received write data to the column control circuit 102, and receives data read from the column control circuit 102 to be outputted to external. An address supplied to the data input/output buffer 104 from external is sent to the column control circuit 102 and the row control circuit 103 via an address register 105.

Moreover, a command supplied to the data input/output buffer 104 from the host 109 is sent to a command interface 106. The command interface 106 receives an external control signal from the host 109, determines whether data inputted to the data input/output buffer 104 is write data or a command or an address, and, if a command, receives the data and transfers the data to a state machine 107 as a command signal.

The state machine 107 performs management of this nonvolatile memory overall, receives a command from the host 109, via the command interface 106, and performs management of read, write, erase, input/output of data, and so on.

In addition, it is also possible for the external host 109 to receive status information managed by the state machine 107 and judge an operation result. Moreover, this status information is utilized also in control of write and erase.

Furthermore, the state machine 107 controls a voltage generating circuit 110. This control enables the voltage generating circuit 110 to output a pulse of any voltage and any timing.

Now, the pulse formed by the voltage generating circuit 110 can be transferred to any line selected by the column control circuit 102 and the row control circuit 103. These column control circuit 102, row control circuit 103, state machine 107, voltage generating circuit 110, and so on, configure a control circuit in the present embodiment.

[Memory Cell Array 101]

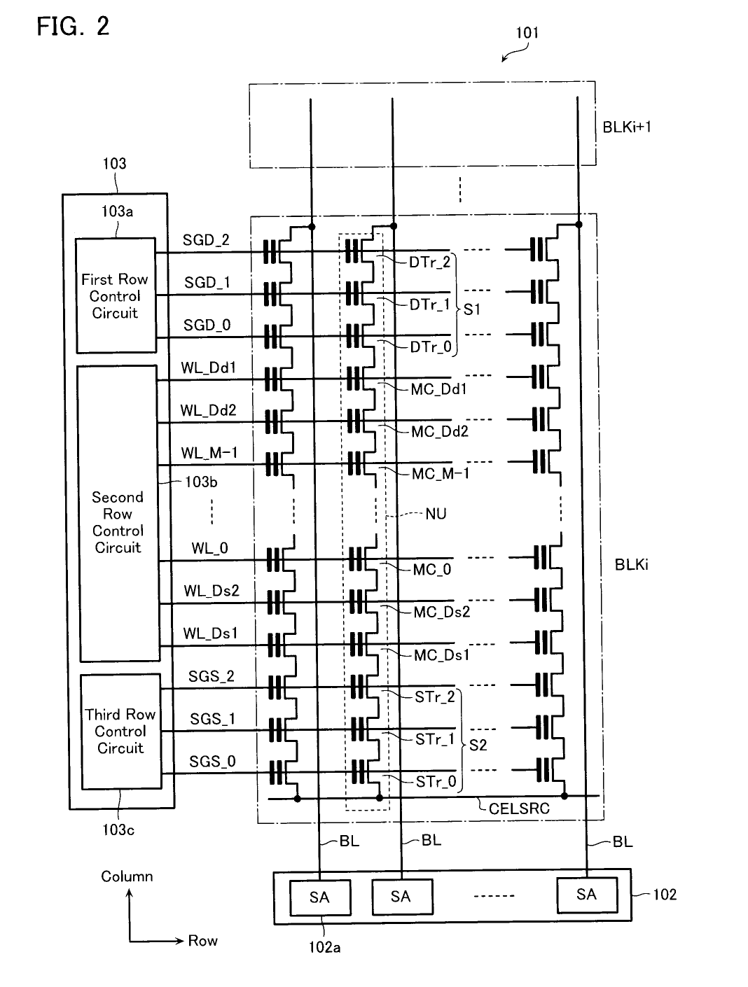

FIG. 2 is a circuit diagram showing a configuration of the memory cell array 101. As shown in FIG. 2, the memory cell array 101 is configured having NAND cell units NU arranged therein, each of the NAND cell units NU having select gate transistors S1 and S2 respectively connected, via dummy cells MC_Ds1, MC_Ds2, MC_Dd1, and MC_Dd2, to both ends of a NAND string, the NAND string having M electrically rewritable nonvolatile memory cells MC_0 to MC_M−1 connected in series therein, sharing a source and a drain.

The NAND cell unit NU has one end (a select gate transistor S1 side) connected to the bit line BL and the other end (a select gate transistor S2 side) connected to a common source line CELSRC. In addition, control gate electrodes of the memory cells MC_0 to MC_M−1 are respectively connected to word lines WL_0 to WL_M−1. Similarly, control gate electrodes of the dummy cells MC_Ds1, MC_Ds2, MC_Dd1, and MC_Dd2 are respectively connected to dummy word lines WL_Ds1, WL_Ds2, WL_Dd1, and WL_Dd2. The bit line BL is connected to a sense amplifier 102a of the column control circuit 102, and the word lines WL_0 to WL_M−1 and the dummy word lines WL_Ds1, WL_Ds2, WL_Dd1, and WL_Dd2 are connected to a second row control circuit (second voltage application circuit) 103b in the row control circuit 103. Note that the second row control circuit 103b controls voltages of the word lines WL_0 to WL_M−1 and the dummy word lines WL_Ds1, WL_Ds2, WL_Dd1, and WL_Dd2, independently.

In the present embodiment, the select gate transistor S1 includes three drain side transistors DTr_0 to DTr_2. These three drain side transistors DTr_0 to DTr_2 are connected in series so as to share a source and a drain. In addition, control gate electrodes of these drain side transistors DTr_0 to DTr_2 are respectively connected to drain gate lines SGD_0 to SGD_2. These drain gate lines SGD_0 to SGD_2 are connected to a first row control circuit (first voltage application circuit) 103a in the row control circuit 103. The first row control circuit 103a applies the drain gate lines SGD_0 to SGD_2 with a voltage supplied from the voltage generating circuit 110, with an identical timing. As a result, the first row control circuit 103a renders the three drain side transistors DTr_0 to DTr_2 in a conductive state synchronously. Note that the drain gate lines SGD_0 to SGD_2 may be electrically short-circuited, for example. Moreover, even if timings at which voltages are supplied to the drain gate lines SGD_0 to SGD_2 are slightly misaligned due to an effect of wiring line resistance or parasitic capacitance, and so on, such a misalignment of timing is assumed to be in a category of (to fall in a range of) identical timing. Moreover, even if timings at which the three drain side transistors DTr_0 to DTr_2 attain a conductive state are slightly misaligned, such a misalignment of timing is assumed to be in a category of synchronicity.

Moreover, in the present embodiment, the select gate transistor S2 includes three source side transistors STr_0 to STr_2. These three source side transistors STr_0 to STr_2 are connected in series so as to share a source and a drain. In addition, control gate electrodes of these source side transistors STr_0 to STr_2 are respectively connected to source gate lines SGS_0 to SGS_2. These source gate lines SGS_0 to SGS_2 are connected to a third row control circuit (third voltage application circuit) 103c in the row control circuit 103. The third row control circuit 103c applies the source gate lines SGS_0 to SGS_2 with a voltage supplied from the voltage generating circuit 110, with an identical timing. As a result, the third row control circuit 103c renders the three source side transistors STr_0 to STr_2 in a conductive state synchronously. Note that the source gate lines SGS_0 to SGS_2 may be electrically short-circuited, for example. Moreover, even if timings at which voltages are supplied to the source gate lines SGS_0 to SGS_2 are slightly misaligned due to an effect of wiring line resistance or parasitic capacitance, and so on, such a misalignment of timing is assumed to be in a category of identical timing. Moreover, even if timings at which the three source side transistors STr_0 to STr_2 attain a conductive state are slightly misaligned, such a misalignment of timing is assumed to be in a category of synchronicity.

In the case of 2 bits/cell where 2 bits of data are stored in one memory cell MC, data stored in the plurality of memory cells MC connected to one word line WL configures 2 pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 101 is M, and, in the case of 2 bits/cell, the number of pages in one block is M×2 pages.

Note that in the example shown in FIG. 2, the NAND cell unit NU comprises four dummy cells MC_Ds1, MC_Ds2, MC_Dd1, and MC_Dd2, but the number of dummy cells is appropriately adjustable, and the dummy cell itself may also be omitted. Moreover, in the example shown in FIG. 2, the select gate transistor S1 includes three drain side transistors DTr_0 to DTr_2, and the select gate transistor S2 includes three source side transistors STr_0 to STr_2. However, the number of transistors included in the select gate transistors S1 and S2 is appropriately adjustable.

[Stacked Structure]

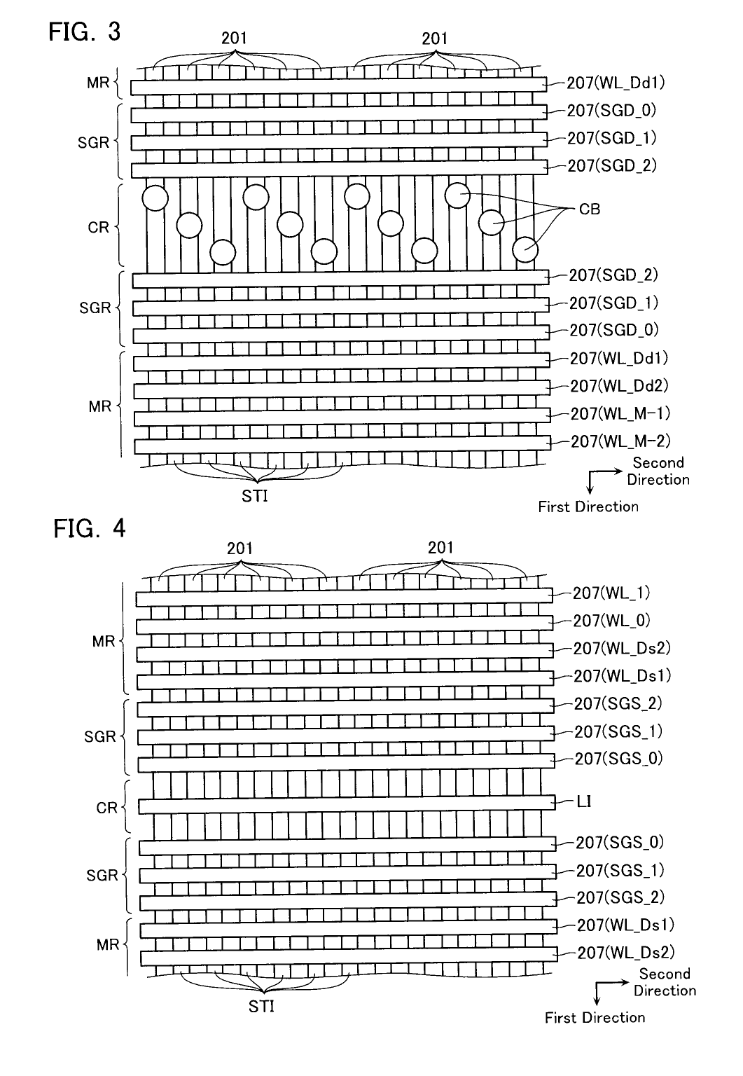

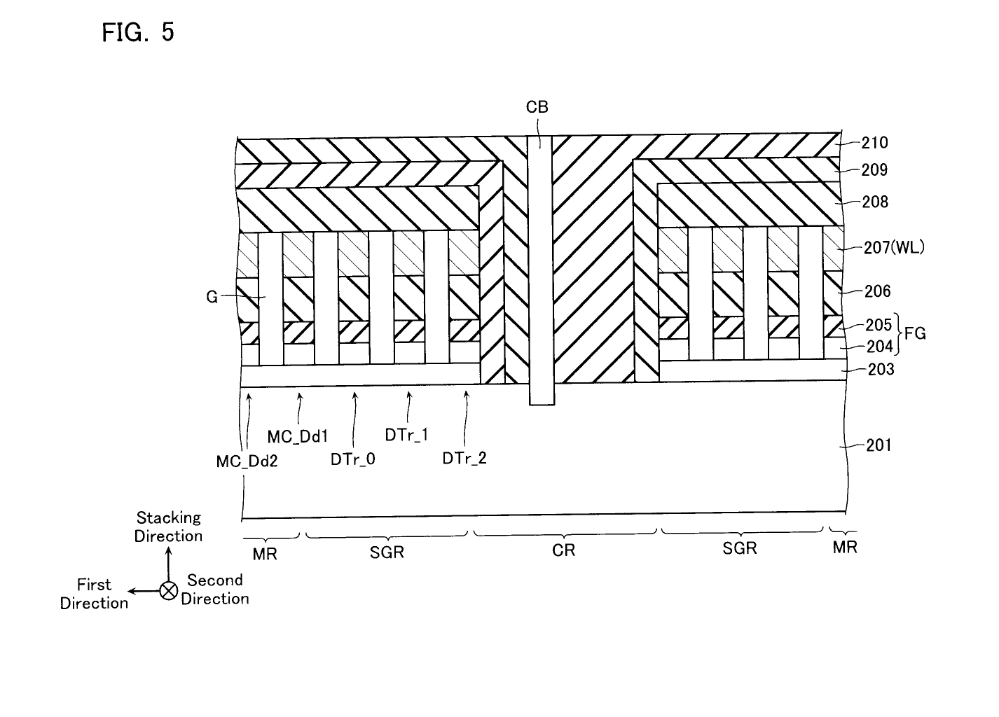

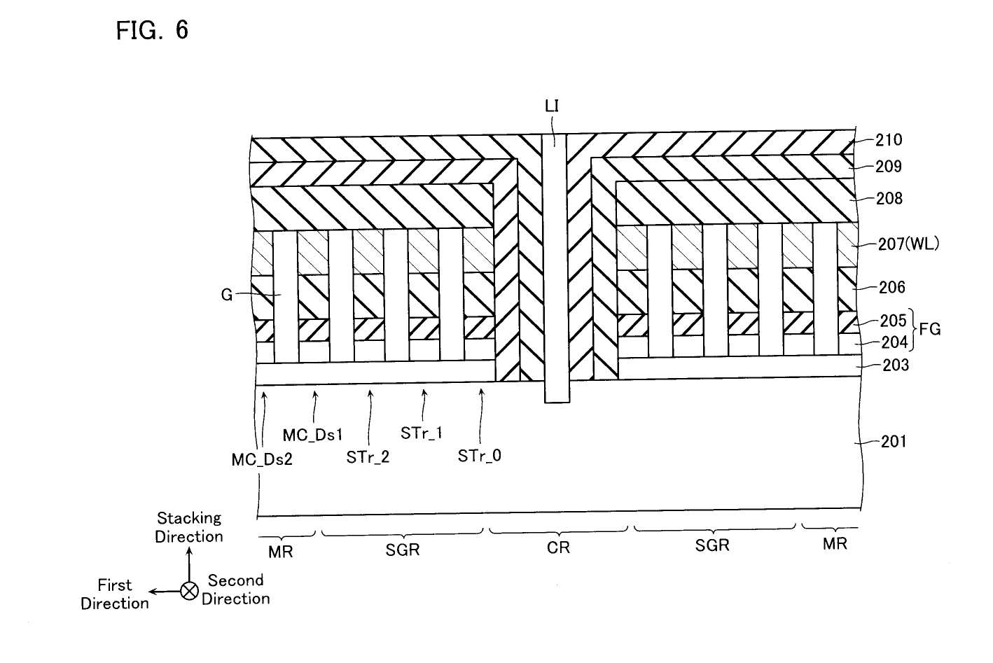

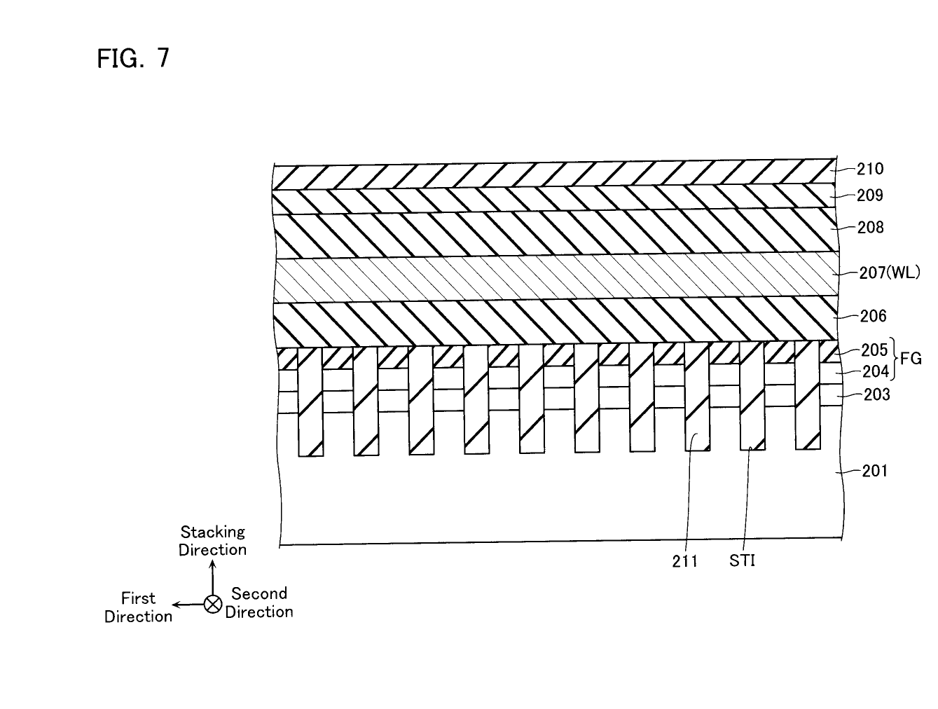

FIGS. 3 and 4 are schematic plan views showing a structure of part of the nonvolatile semiconductor memory device according to the first embodiment. FIGS. 5 and 6 are respective cross-sectional views taken along a second direction and viewed from a first direction, of part of the structure shown in FIGS. 3 and 4. FIG. 7 is a cross-sectional view taken along the first direction and viewed from the second direction, of part of the same structure. Note that in FIGS. 3 and 4, part of a configuration is omitted. As shown in FIGS. 3 and 4, the nonvolatile semiconductor memory device according to the present embodiment is provided with a memory region MR, a select gate region SGR, and a contact region CR that are aligned in the first direction. Formed in the memory region MR are the plurality of memory cells MC_0 to MC_M−1 and the dummy cells MC_Ds1, MC_Ds2, MC_Dd1, and MC_Dd2. Formed in the select gate region SGR are the select gate transistors S1 or S2. Formed in the contact region CR are a bit line contact CB or a source line contact LI. The bit line contact CB connects a semiconductor layer 201 and the bit line BL. The source line contact LI connects the semiconductor layer 201 and the source line CELSRC (FIG. 2).

As shown in FIGS. 3, 4, and 6, the nonvolatile semiconductor memory device according to the present embodiment comprises a plurality of the semiconductor layers 201 arranged in plurality in the second direction via an STI and extending in the first direction. Moreover, the memory region MR and the select gate region SGR of the same semiconductor memory device are provided with a plurality of conductive layers 207 arranged in plurality in the first direction and extending in the second direction.

The plurality of semiconductor layers 201 function as channel layers of the memory cells MC_0 to MC_M−1, the dummy cells MC_Ds1, MC_Ds2, MC_Dd1, and MC_Dd2, the source side transistors STr_0 to STr_2, and the drain side transistors DTr_0 to DTr_2 (hereafter, called “memory cells MC, and so on”). Moreover, the plurality of conductive layers 207 function as control gate electrodes of the memory cells MC, and so on, and as the word lines WL_0 to WL_M−1, the dummy word lines WL_Ds1, WL_Ds2, WL_Dd1, and WL_Dd2, the drain gate lines SGD_0 to SGD_2, and the source gate lines SGS_0 to SGS_2.

As shown in FIGS. 5 and 6, the memory cells MC_0 to MC_M−1 include the following, sequentially stacked therein, namely: the semiconductor layer 201; a first insulating layer 203 functioning as a tunnel insulating layer; a first charge accumulation layer 204 and a second charge accumulation layer 205 that function as a charge accumulation layer (floating gate electrode); a second insulating layer 206 functioning as an inter-gate insulating layer; and the conductive layer 207 functioning as the word line WL (control gate electrode, first conductive layer). As shown in FIG. 7, the semiconductor layer 201 is multiply divided in the second direction via the STI. Note that the STI is implanted with an insulating layer 211. Moreover, film thicknesses of each of the layers are appropriately adjustable, but the film thickness of the first insulating layer 203 is, for example, 20 nm or less.

As shown in FIGS. 5 and 6, in the present embodiment, the memory cells MC_0 to MC_M−1, the dummy cells MC_Ds1, MC_Ds2, MC_Dd1, and MC_Dd2, the source side transistors STr_0 to STr_2, and the unillustrated drain side transistors DTr_0 to DTr_2 (hereafter, called “memory cells MC, and so on”) have an identical configuration. That is, the memory cells MC, and so on, are configured stacking identical films with identical film thicknesses in an identical order. Therefore, not only the memory cells MC_0 to MC_M−1 and the dummy cells MC_Ds1, MC_Ds2, MC_Dd1, and MC_Dd2, but also the source side transistors STr_0 to STr_2 and the unillustrated drain side transistors DTr_0 to DTr_2 include the charge accumulation layer (floating gate electrode). Moreover, as shown in FIGS. 5 and 6, in the present embodiment, widths in the first direction of the memory cells MC, and so on, are identical. Furthermore, between these memory cells MC, and so on, is insulated by an air gap G.

As shown in FIGS. 5 and 6, upper surfaces of the memory cells MC, and so on, are covered by an insulating layer 208, and an upper surface of the insulating layer 208 and side surfaces of the source side transistor and the drain side transistor closest to the contact region CR are covered by an insulating layer 209. In addition, the insulating layer 209, the source line contact LI, and the bit line contact CB are covered by an insulating layer 210.

The first insulating layer 203 is configured from, for example, silicon oxide (SiO₂). In addition, the first charge accumulation layer 204 is configured from, for example, n type polysilicon. The second charge accumulation layer 205 is configured from, for example, silicon nitride (SiN). Moreover, a metal layer may be formed on an upper surface of the second charge accumulation layer 205. The second insulating layer 206 may be formed from, for example, silicon oxide (SiO₂), but may also adopt a variety of configurations such as a stacked structure configured from hafnium oxide (HfOₓ), silicon oxide (SiO₂), and hafnium oxide (HfOₓ). Moreover, an upper surface of the second insulating layer 206 may be provided with a barrier film such as a stacked film of tantalum nitride (TaN) and tungsten nitride (WN). In addition, the conductive layer 207 is configured from, for example, tungsten (W). The insulating layer 208 is configured from, for example, silane (SiH₄), or the like. Moreover, the insulating layer 210 is configured from, for example, polysilazane, or the like. Note that materials of each of the layers may be changed appropriately. For example, the first charge accumulation layer 204 may be configured from p type polysilicon, and so on. Moreover, configurations of the tunnel insulating layer, the charge accumulation layer FG, the inter-gate insulating layer, and the word line WL may be changed appropriately.

As shown in FIG. 3, the bit line contact CB is provided to each of the semiconductor layers 201 arranged in the second direction. Moreover, positions in the first direction of the bit line contacts CB connected to fellow semiconductor layers 201 adjacent in the second direction, are different.

In addition, as shown in FIG. 4, the source line contact LI is provided commonly to the plurality of semiconductor layers 201 arranged in the second direction.

As described above, in the present embodiment, the above-mentioned memory cells MC, and so on, all have an identical film structure. That is, they include, stacked sequentially therein: the semiconductor layer 201; the first insulating layer 203; the first charge accumulation layer 204 and the second charge accumulation layer 205; the second insulating layer 206; and the conductive layer 207. Moreover, film thicknesses of these layers are all identical among the above-mentioned memory cells MC, and so on. Furthermore, in both the drain side transistors DTr_0 to DTr_2 configuring the select gate transistor S1 and the source side transistors STr_0 to STr_2 configuring the select gate transistor S2, the charge accumulation layer and the control gate are configured electrically independently. As will be mentioned later, a semiconductor memory device having such a configuration can be easily manufactured.

Moreover, in the present embodiment, the select gate transistor S1 includes the drain side transistors DTr_0 to DTr_2, and these drain side transistors DTr_0 to DTr_2 include the charge accumulation layer. Therefore, in the present embodiment, it is possible to accumulate a charge in the charge accumulation layer of the drain side transistors DTr_0 to DTr_2, and adjust a threshold value of the select gate transistor S1.

Moreover, in the present embodiment, the charge accumulation layers of these drain side transistors DTr_0 to DTr_2 are each electrically independent floating gate electrodes. Therefore, it is possible to reduce area and suitably control an amount of charge accumulated, for one charge accumulation layer.

Moreover, in the present embodiment, the control gate electrodes of these drain side transistors DTr_0 to DTr_2 are applied with an identical voltage at an identical timing, by the first voltage application circuit. Therefore, the first voltage application circuit can be configured comparatively simply.

Moreover, in the present embodiment, the select gate transistor S1 includes three drain side transistors DTr_0 to DTr_2, and these three drain side transistors DTr_0 to DTr_2 each independently include the charge accumulation layer. Therefore, even when it is difficult to suitably adjust a charge of the drain side transistor DTr_2 having the smallest distance from the bit line contact CB, utilizing the drain side transistor DTr_1 adjacent to this drain side transistor DTr_2 as a dummy makes it possible to suitably adjust a charge of the drain side transistor DTr_0 having the largest distance from the bit line contact CB and suitably adjust the threshold value of the select gate transistor S1.

Moreover, in the present embodiment, widths in the first direction of the above-mentioned memory cells MC, and so on, are identical. As will be mentioned later, such a configuration can be manufactured with good precision.

[Method of Manufacturing]

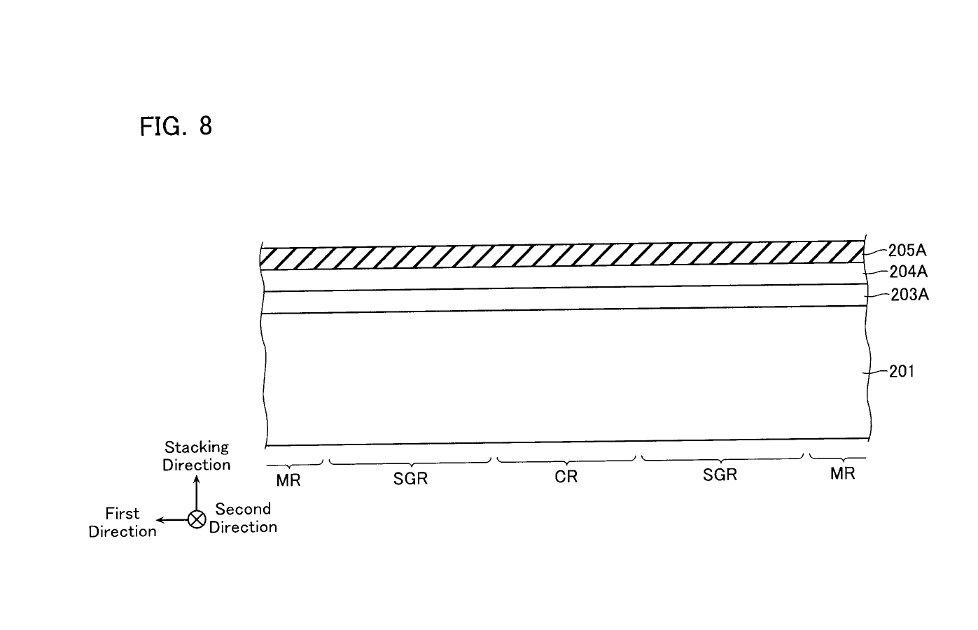

Next, a method of manufacturing the nonvolatile semiconductor memory device according to the present embodiment will be described with reference to FIGS. 8 to 18. FIGS. 8 to 18 are cross-sectional views showing manufacturing steps of the same nonvolatile semiconductor memory device.

As shown in FIG. 8, the following are stacked sequentially on the semiconductor layer 201, namely: an insulating layer 203A which will be the first insulating layer 203; a charge accumulation layer 204A which will be the first charge accumulation layer 204; and a charge accumulation layer 205A which will be the second charge accumulation layer 205.

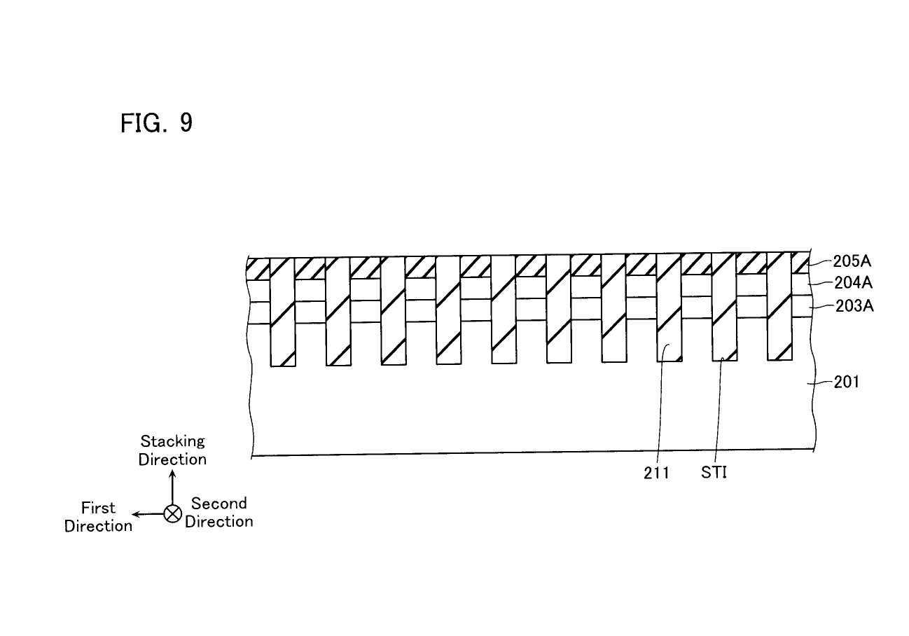

Next, as shown in FIG. 9, the semiconductor layer 201, the insulating layer 203A, the charge accumulation layer 204A, and the charge accumulation layer 205A are divided in the second direction, and a trench formed by this division is implanted with the insulating layer 211.

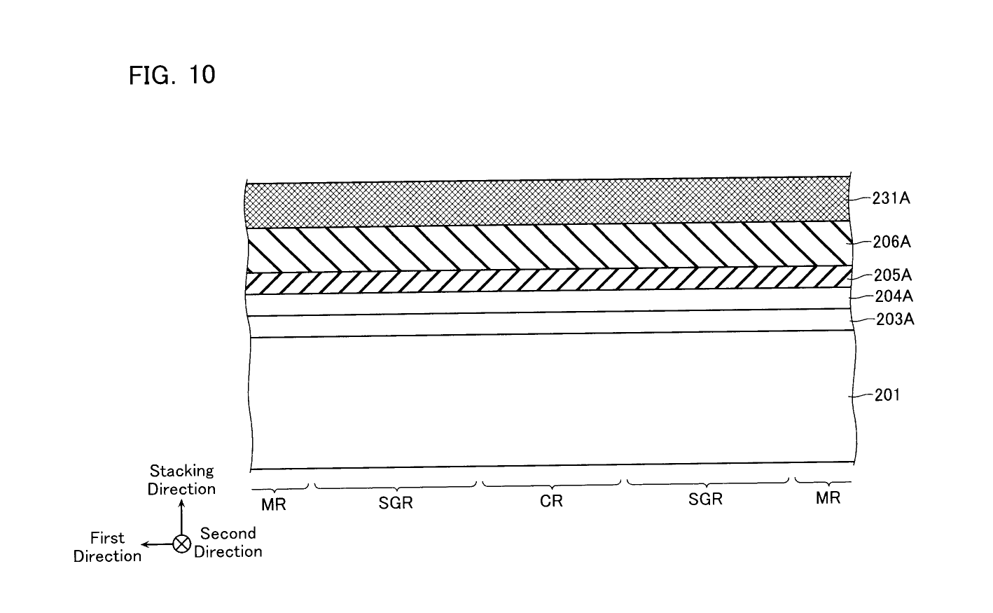

Next, as shown in FIG. 10, the following are stacked sequentially on the charge accumulation layer 205A and the insulating layer 211 (not illustrated), namely: an insulating layer 206A which will be the second insulating layer 206; and a sacrifice layer 231A.

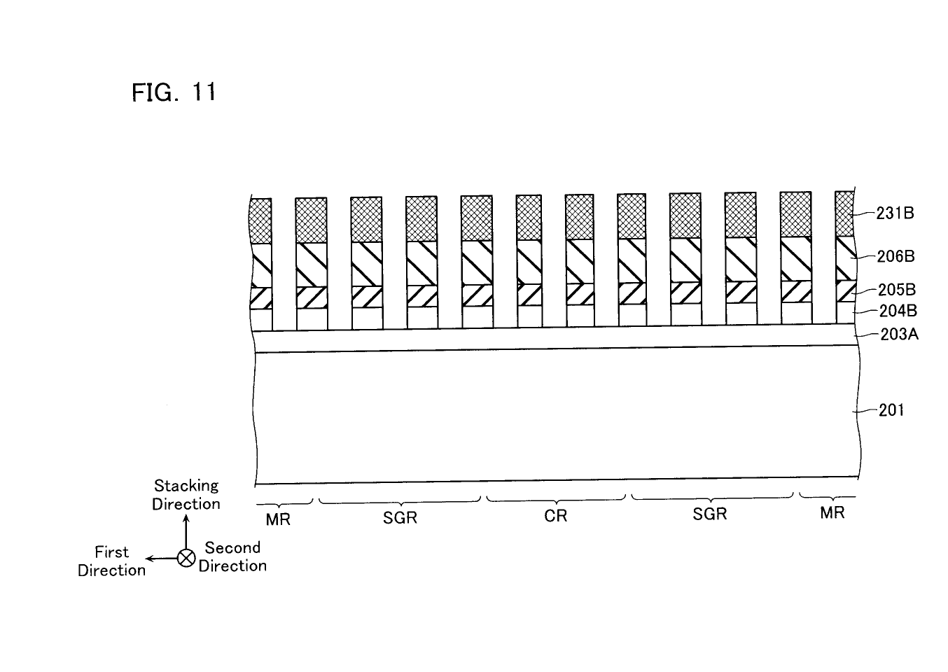

Next, as shown in FIG. 11, the insulating layer 203A, the charge accumulation layer 204A, the charge accumulation layer 205A, the insulating layer 206A, and the sacrifice layer 231A are divided in the first direction in the memory region MR, the select gate region SGR, and the contact region CR to form an insulating layer 203B, a charge accumulation layer 204B, a charge accumulation layer 205B, an insulating layer 206B, and a sacrifice layer 231B. Note that in the present embodiment, the insulating layer 203A, the charge accumulation layer 204A, the charge accumulation layer 205A, the insulating layer 206A, and the sacrifice layer 231A are divided with an identical spacing in the first direction. Therefore, the insulating layer 203B, the charge accumulation layer 204B, the charge accumulation layer 205B, the insulating layer 206B, and the sacrifice layer 231B are separated by an identical spacing and have an identical width, with respect to the first direction.

Division of the insulating layer 203A, the charge accumulation layer 204A, the charge accumulation layer 205A, the insulating layer 206A, and the sacrifice layer 231A may be performed by depositing a resist on the sacrifice layer 231A and performing the likes of lithography and etching. Moreover, the division may be performed by further forming another sacrifice layer on the sacrifice layer 231A, dividing the other sacrifice layer in the first direction by the likes of lithography and etching, further forming another sacrifice layer on a sidewall of the divided other sacrifice layer, and performing etching using the other sacrifice layer formed on this sidewall as a mask. Furthermore, such a step may be repeatedly performed.

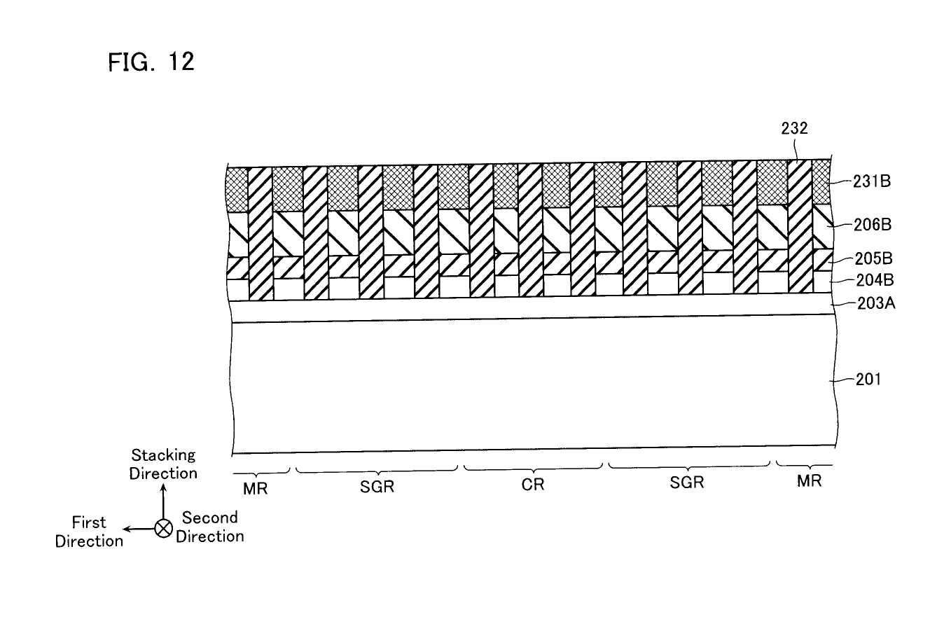

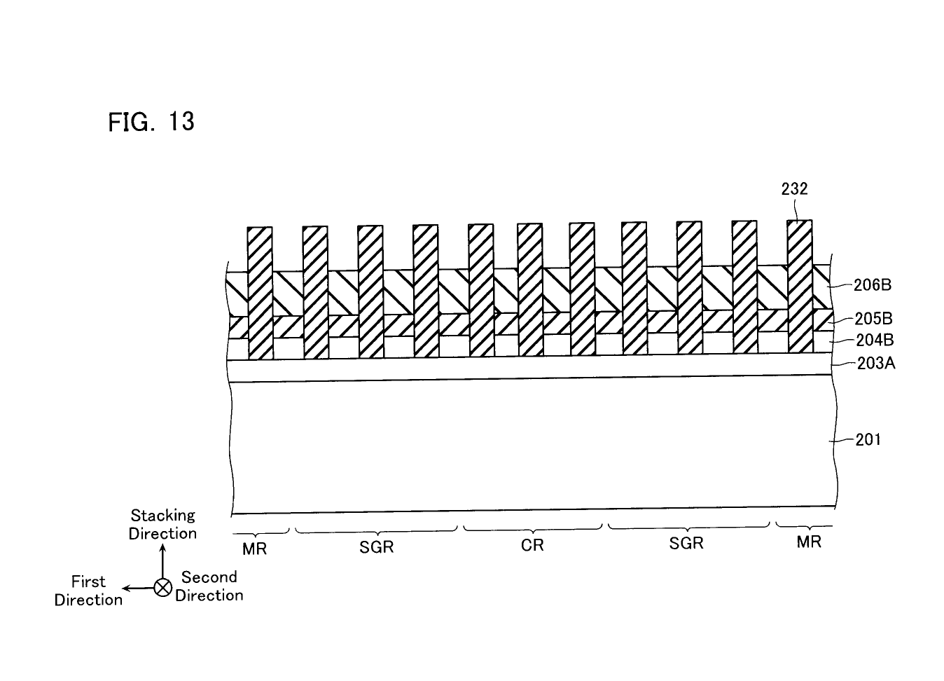

Next, as shown in FIG. 12, a region between the insulating layer 203B, the charge accumulation layer 204B, the charge accumulation layer 205B, the insulating layer 206B, and the sacrifice layer 231B divided in the first direction, is further implanted with a sacrifice layer 232. Moreover, as shown in FIG. 12, a height of an upper end of the sacrifice layer 232 is aligned with a height of an upper end of the sacrifice layer 231B. Next, as shown in FIG. 13, the sacrifice layer 231B is removed.

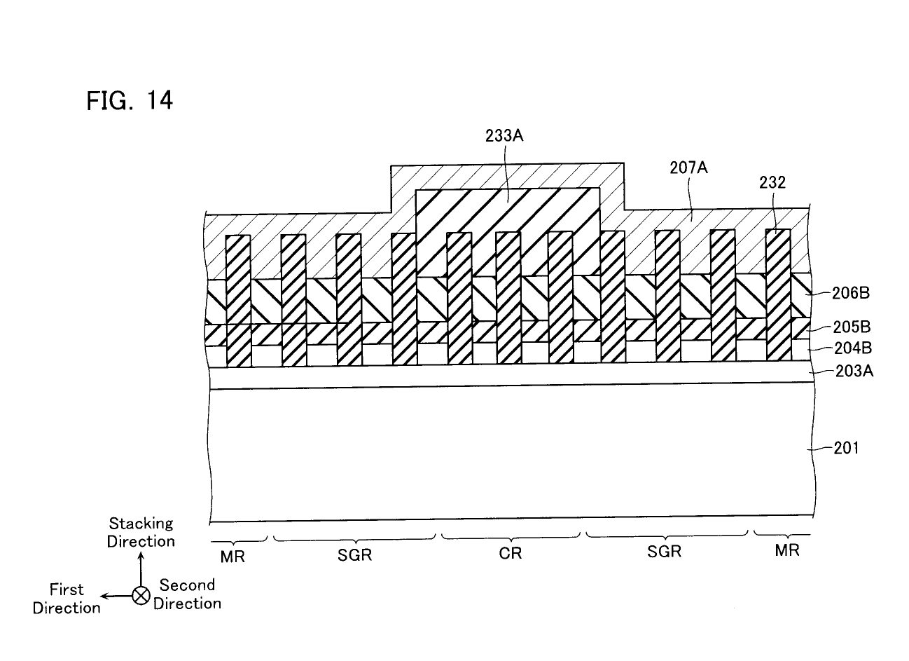

Next, as shown in FIG. 14, a sacrifice layer 233A covering an upper surface of the insulating layer 206B and an upper surface and side surfaces of the sacrifice layer 232, is formed in the contact region CR. Moreover, as shown in FIG. 14, a conductive layer 207A which will be the conductive layer 207 is formed in the memory region MR, the select gate region SGR, and the contact region CR. The conductive layer 207A contacts the upper surface of the insulating layer 206B in the memory region MR and the select gate region SGR.

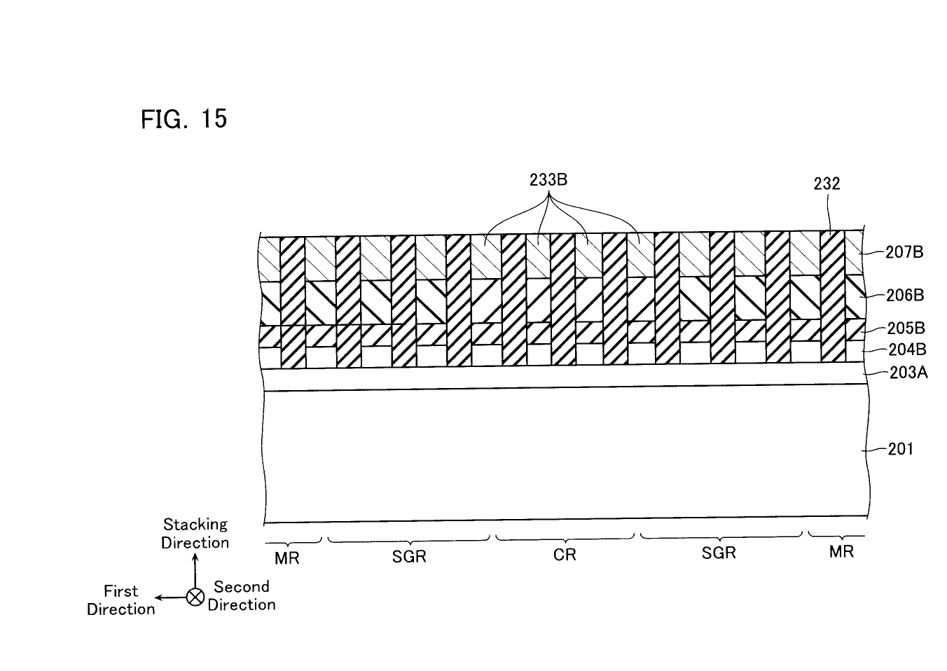

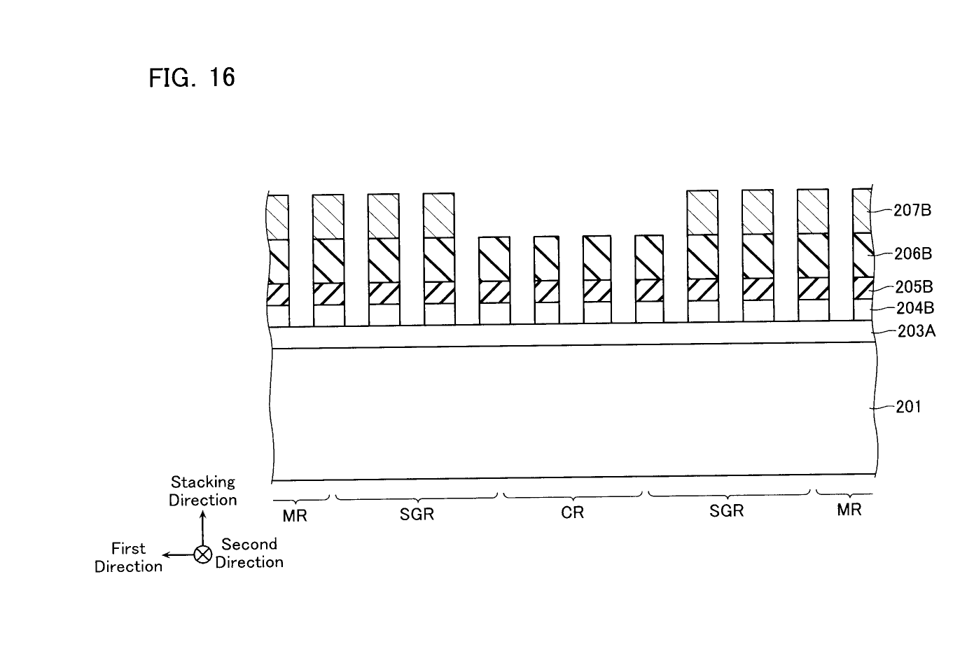

Next, as shown in FIG. 15, CMP is performed using the sacrifice layer 233A as a stopper film, and heights of upper ends of the sacrifice layer 233A and the conductive layer 207A are aligned with the height of the upper end of the sacrifice layer 232. As a result, these configurations are divided in the first direction to form a sacrifice layer 233B and a conductive layer 207B. This step results in the memory cells MC, and so on, being formed. Next, as shown in FIG. 16, the sacrifice layer 232 and the sacrifice layer 233B are removed.

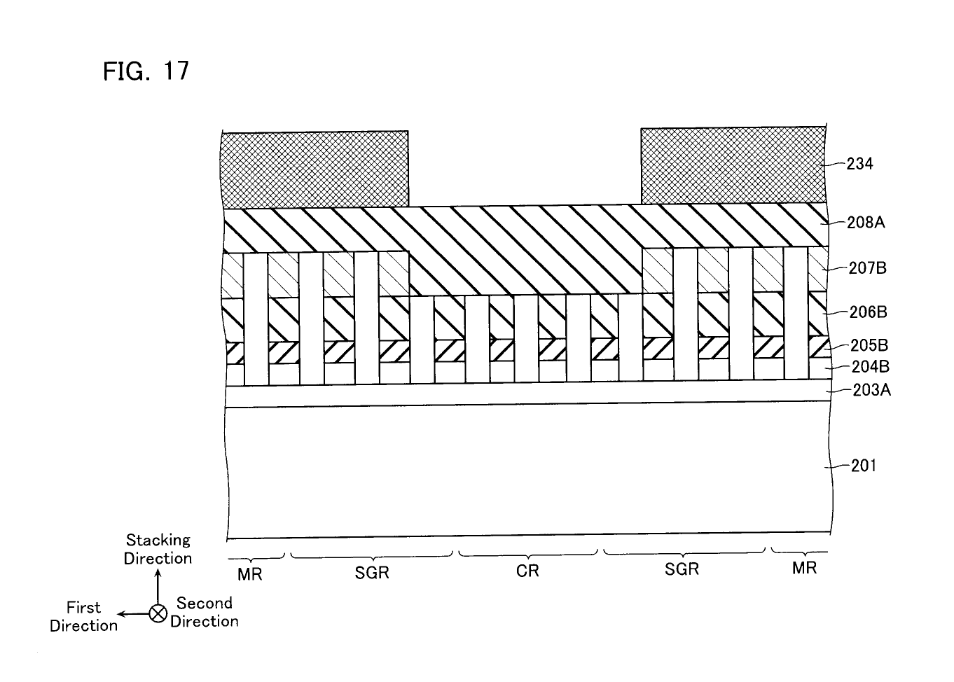

Next, as shown in FIG. 17, an insulating layer 208A which will be the insulating layer 208 is formed in the memory region MR, the select gate region SGR, and the contact region CR. As shown in FIG. 17, the insulating layer 208A covers an upper surface of the conductive layer 207B in the memory region MR and the select gate region SGR, and covers an upper surface of the insulating layer 206B in the contact region CR. Note that the insulating layer 208A is formed by a material having poor implanting properties such as plasma silane (P—SiH₄), for example. As a result, a gap G is formed between the memory cells MC, and so on, adjacent in the first direction.

Next, as shown in FIG. 17, a resist 234 is formed on an upper surface of the insulating layer 208A. In the present embodiment, the resist 234 covers the memory region MR and the select gate region SGR, and does not cover the contact region CR.

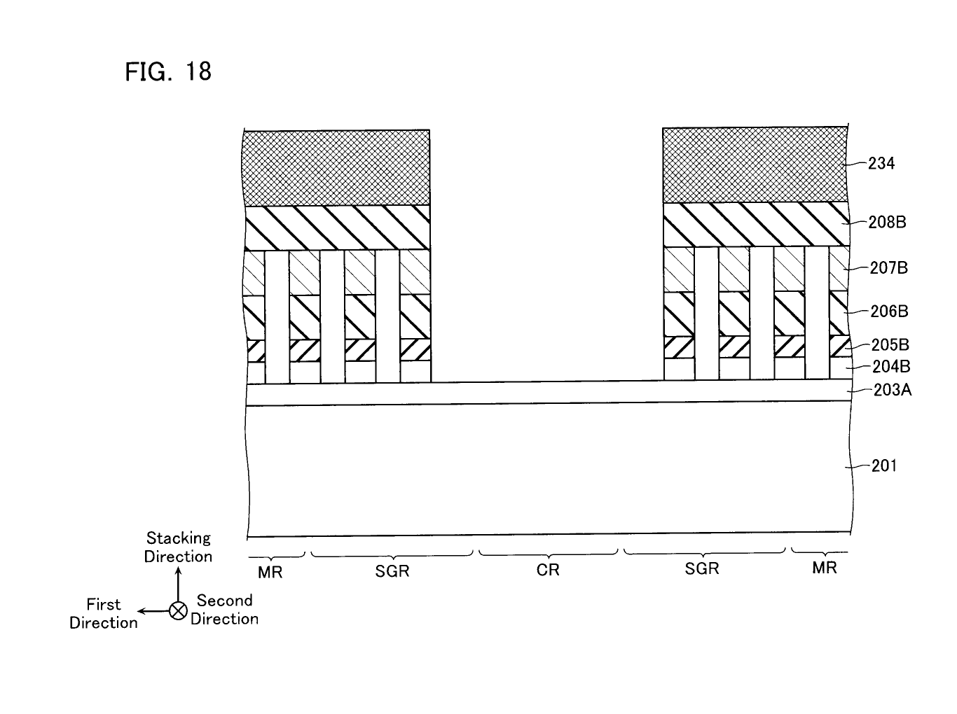

Next, as shown in FIG. 18, the insulating layer 203A, the charge accumulation layer 204B, the charge accumulation layer 205B, and the insulating layer 208A positioned in the contact region CR are removed using the resist 234 as a mask, to expose an upper surface of the semiconductor layer 201. Note that in this step, the insulating layer 208A becomes an insulating layer 208B divided in the first direction in the contact region CR.

Next, as shown in FIGS. 5 and 6, an upper surface of the insulating layer 208B and side surfaces of the source side transistor and the drain side transistor closest to the contact region CR are covered by the insulating layer 209; the memory region MR, the select gate region SGR, and the contact region CR are implanted by the insulating layer 210; and a contact hole is formed in the insulating layer 210 positioned in the contact region CR, thereby forming therein the bit line contact CB and the source line contact LI.

Now, as described with reference to FIG. 2, the semiconductor memory device according to the present embodiment includes the select gate transistors S1 and S2 connected to both ends of the NAND string. Now, it is also conceivable to remove part of the inter-gate insulating layer and electrically connect the layers forming the charge accumulation layer FG and the word line WL, in the transistors configuring the select gate transistors S1 and S2.

However, in the case where, for example, film thickness of the layers forming the charge accumulation layer FG is small, sometimes, the charge accumulation layer FG gets removed and, furthermore, part of the tunnel insulating layer gets removed, along with the inter-gate insulating layer. In this case, the layer forming the word line WL and the semiconductor layer sometimes get short-circuited. Note that such a phenomenon begins to occur comparatively frequently when, for example, the film thickness of the charge accumulation layer FG becomes about 20 nm or less.

In this regard, in the present embodiment, as described with reference to FIGS. 8 to 18, the select gate transistors S1 and S2 are formed by transistors that include the charge accumulation layer and the control gate. Therefore, a step for removing part of the inter-gate insulating layer becomes unnecessary, and the above-mentioned kind of phenomenon ceases to occur.

Moreover, in the present embodiment, as described with reference to FIG. 11, the insulating layer 203A, the charge accumulation layer 204A, the charge accumulation layer 205A, the insulating layer 206A, and the sacrifice layer 231A are divided with an identical spacing in the first direction. Such an embodiment makes it possible to perform processing with better precision, compared to the case where, for example, spacing or width are made dissimilar for part of the configuration.

Note that FIGS. 8 to 18 described a process in which the sacrifice layer 231A is formed on the insulating layer 206A, the sacrifice layer 231A is divided in the first direction to configure the sacrifice layer 231B, the sacrifice layer 232 is formed between the sacrifice layers 231B adjacent in the first direction, the sacrifice layer 231B is removed, and the conductive layer 207A is formed in a portion between the sacrifice layers 232. However, it is also possible for a conductive layer to be formed directly on the insulating layer 206A, for example, and for this conductive layer to be divided in the first direction along with the insulating layer 206A.

### Second Embodiment

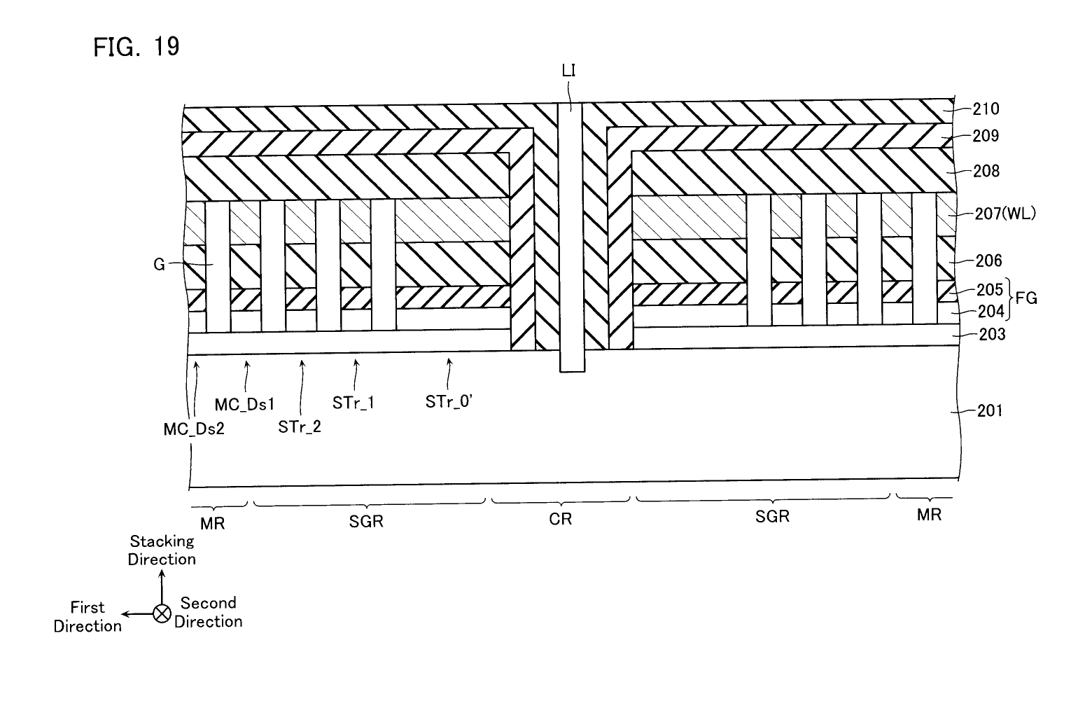

Next, a nonvolatile semiconductor memory device according to a second embodiment will be described with reference to FIG. 19. FIG. 19 is a schematic cross-sectional view showing a configuration of part of the nonvolatile semiconductor memory device according to the second embodiment. Note that in the description below, portions similar to those of the first embodiment are assigned with identical reference symbols to those assigned in the first embodiment, and descriptions thereof will be omitted.

As shown in FIG. 19, the nonvolatile semiconductor memory device according to the present embodiment is basically configured similarly to the nonvolatile semiconductor memory device according to the first embodiment. However, in the present embodiment, a width in the first direction of a source side transistor STr_0′ closest to the contact region CR is larger than the width in the first direction of the other memory cells MC, and so on. As a result, in the present embodiment, cutoff in the source side transistor STr_0′ can be more reliably performed. Note that it is also possible for a width in the first direction of a drain side transistor closest to the contact region CR to be set larger than the width in the first direction of the other memory cells MC, and so on.

[Others]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory string including a plurality of memory cells connected in series;
a first select gate transistor connected to one end of the memory string; and
a first voltage application circuit that controls the first select gate transistor,
the first select gate transistor including a plurality of first transistors connected in series, and
the first voltage application circuit performing application of a voltage so as to render the plurality of first transistors in a conductive state synchronously.

2. The semiconductor memory device according to claim 1, wherein
the first transistor comprises:
a semiconductor layer;
a first floating gate electrode facing the semiconductor layer; and
a first control gate electrode facing the first floating gate electrode.

3. The semiconductor memory device according to claim 2, wherein
the memory cell comprises:
the semiconductor layer;
a second floating gate electrode facing the semiconductor layer; and
a second control gate electrode facing the second floating gate electrode,
a film thickness of the second floating gate electrode matches a film thickness of the first floating gate electrode, and
a film thickness of the second control gate electrode matches a film thickness of the first control gate electrode.

4. The semiconductor memory device according to claim 2, wherein
the semiconductor layer extends in a first direction,
a plurality of the first floating gate electrodes are arranged in the first direction along the semiconductor layer, and
widths of the plurality of first floating gate electrodes are matched in the first direction.

5. The semiconductor memory device according to claim 1, wherein
the semiconductor layer extends in a first direction,
a plurality of the first floating gate electrodes are arranged in the first direction along the semiconductor layer, and
widths in the first direction of the plurality of first floating gate electrodes excluding the one of the first floating gate electrodes most distant from the memory string, of the plurality of first floating gate electrodes, are matched.

6. The semiconductor memory device according to claim 1, further comprising:
a second voltage application circuit,
wherein the memory cell comprises:
the semiconductor layer;
a second floating gate electrode facing the semiconductor layer; and
a second control gate electrode facing the second floating gate electrode, and
the second voltage application circuit controls voltages of a plurality of the second control gate electrodes independently.

7. The semiconductor memory device according to claim 1, further comprising:
a second select gate transistor connected to the other end of the memory string; and
a third voltage application circuit that controls the second select gate transistor,
wherein
the second select gate transistor includes a plurality of second transistors connected in series, and
the third voltage application circuit performs application of a voltage so as to render the plurality of second transistors in a conductive state synchronously.

8. The semiconductor memory device according to claim 7, wherein
the second transistor comprises:
a semiconductor layer;
a third floating gate electrode facing the semiconductor layer; and
a third control gate electrode facing the third floating gate electrode.

9. The semiconductor memory device according to claim 2, wherein
the first select gate transistor comprises at least three of the first floating gate electrodes.

10. A method of manufacturing a semiconductor memory device, the semiconductor memory device comprising: a plurality of memory cells provided in a first region on a semiconductor layer; and a plurality of first transistors provided in a second region on the semiconductor layer, the method comprising:
stacking on the semiconductor layer a first insulating layer which will be a gate insulating layer of the memory cell and the first transistor;
stacking on the first insulating layer a floating gate electrode formation layer which will be a floating gate electrode of the memory cell and the first transistor; and
dividing the floating gate electrode formation layer in the first direction, in the first region and the second region.

11. The method of manufacturing a semiconductor memory device according to claim 10, further comprising:
dividing the floating gate electrode formation layer with an identical spacing, in the first region and the second region.

12. The method of manufacturing a semiconductor memory device according to claim 10, further comprising:
dividing the floating gate electrode formation layer with an identical spacing, from the first region to a certain position in the second region.

13. The method of manufacturing a semiconductor memory device according to claim 10, further comprising:
stacking on the floating gate electrode formation layer a second insulating layer which will be an inter-gate insulating layer of the memory cell;
stacking a first sacrifice layer on the second insulating layer;
dividing the second insulating layer and the first sacrifice layer, along with the floating gate electrode formation layer, in the first direction, in the first region and the second region;
forming a second sacrifice layer in a region between the first sacrifice layers divided in the first direction;
removing the first sacrifice layer to expose an upper surface of the second insulating layer;
forming on the exposed upper surface of the second insulating layer a first conductive layer which will be a control gate electrode of the memory cell; and
removing the second sacrifice layer.

14. The method of manufacturing a semiconductor memory device according to claim 13, wherein
the semiconductor memory device further comprises:
a contact contacting the semiconductor layer in a third region adjacent to the first region via the second region, on the semiconductor layer, and
the method further comprises:
after removing the first sacrifice layer and before forming the first conductive layer, forming a third sacrifice layer on upper surfaces of the second insulating layer and the second sacrifice layer, in the third region; and
after forming the first conductive layer, removing the third sacrifice layer.

15. A semiconductor memory device, comprising:
a semiconductor layer extending in a first direction;
a plurality of first floating gate electrodes that are arranged in a first direction along the semiconductor layer and face the semiconductor layer;
a plurality of first control gate electrodes respectively facing the plurality of first floating gate electrodes; and
a first voltage application circuit that applies a first voltage to the plurality of first control gate electrodes with an identical timing.

16. The semiconductor memory device according to claim 15, wherein
widths of the plurality of first floating gate electrodes are matched in the first direction.

17. The semiconductor memory device according to claim 15, wherein
widths in the first direction of a plurality of the floating gate electrodes excluding the one of the first floating gate electrodes closest to the contact, of the plurality of floating gate electrodes, are matched.

18. The semiconductor memory device according to claim 15, further comprising:
a plurality of second floating gate electrodes that are arranged in the first direction along the semiconductor layer, are adjacent in the first direction to the plurality of first floating gate electrodes, and face the semiconductor layer;
a plurality of second control gate electrodes respectively facing the plurality of second floating gate electrodes; and
a second voltage application circuit that controls voltages of the plurality of second control gate electrodes independently.

19. The semiconductor memory device according to claim 15, comprising:
at least three of the first floating gate electrodes.
